(19) United States
(12) Patent Application Publication
(10) Pub. No.: US 2010/0037825 A1
(43) Pub. Date: Feb. 18, 2010

(54) DIFFERENTIATED-TEMPERATURE REACTION CHAMBER

(75) Inventors: Gianluca Valente, Milano (IT); Giacomo Nicolao Maccalli, Novate Milanese (IT); Danilo Crippa, Novara (IT); Franco Preti, Milano (IT)

Correspondence Address: Brannen Law Office, LLC;Nicholas A. Brannen, 104 S. Main Street, Suite #506, Fond du Lac, WI, 54935, US

(73) Assignee: LPE S.P.A., Baranzate (IT)

(21) Appl. No.: 12/159,035

(22) PCT Filed: Dec. 18, 2006
(86) PCT No.: PCT/IB06/03664

§ 371 Date: Oct. 22, 2009

(30) Foreign Application Priority Data
Dec. 28, 2005 (IT) MI2005A002498

(51) Int. Cl. C30B 25/10; H05B 6/02; F27B 14/06

(52) U.S. Cl. 118/724; 219/600

(57) ABSTRACT

The present invention relates to a reaction chamber (1) for an epitaxial reactor, provided with walls delimiting an inner cavity (10), specifically a lower wall (3) and an upper wall (2) and at least two side walls (4,5); the lower wall (3) and the upper wall (2) have different configurations and/or are made of different materials; this allows the lower wall (3) to be heated to a higher temperature than the upper wall (2). The present invention also relates to a method for heating a reaction chamber.

This application is being filed in the United States for the national phase of international application number PCT/IB2006/003664 filed on 18 Dec. 2006 (publication number WO 2007/088420 A2), claiming priority on prior application MI2005A002498 filed in Italy 28 Dec. 2005, the contents of each being hereby incorporated herein by reference.

### DESCRIPTION

The present invention relates to a reaction chamber for an epitaxial reactor and to a method for heating a reaction chamber.

Epitaxial reactors for microelectronics applications are designed for depositing thin layers of a material (generally a semiconductor material) on substrates very smoothly and evenly (this process is often referred to as “epitaxial growth”); in general, substrates before and after deposition are called “wafers”.

Said deposition takes place at high temperatures in an inner (reaction) cavity of a reaction chamber, typically through a CVD [Chemical Vapour Deposition] process.

It is well known that, in the field of epitaxial reactors, reaction chambers are essentially divided into two main categories: “cold-wall” chambers and “hot-wall” chambers; essentially, these terms refer to the temperature of the surface of the cavity wherein epitaxial deposition processes take place.

During the deposition process, the material deposits on both the substrate and the surface of the inner cavity, i.e. on the side of the reaction chamber walls facing the inner cavity; this is particularly true for hot-wall reactors, since the material deposits much more easily and quickly where temperature is high.

During every process, a new thin layer of material deposits on the chamber walls; after several processes, the walls become coated with a thick layer of material.

This thick layer of material modifies the geometry of the reaction cavity of the reaction chamber, thus affecting the flow of reaction gases and hence the subsequent growth processes.

Moreover, said thick layer of material is not perfectly compact and tends to be rough; in fact, the surface of the reaction cavity has not the same quality as the surface of a substrate, so that the material growing on it is not monocrystalline, but polycrystalline. It follows that, during further growth processes, small particles may come off said thick layer and fall onto the growing substrates, thus damaging them.

At present, the most common semiconductor material used in the microelectronics industry is silicon. A very promising material is silicon carbide, although it is not yet widely used in the microelectronics industry.

The epitaxial growth of silicon carbide having such a high quality as required by the microelectronics industry needs very high temperatures, i.e. temperatures higher than 1,500° C. (typically between 1,500° C. and 1,700° C., preferably between 1,550° C. and 1,650° C.), which are therefore much higher than those necessary for the epitaxial growth of silicon, generally between 1,100° C. and 1,200° C. Epitaxial reactors with hot-wall reaction chambers are particularly suitable for obtaining such high temperatures.

Epitaxial reactors for the deposition of silicon carbide are therefore particularly sensitive to the problem of material deposition on the reaction chamber walls. Furthermore, silicon carbide is a material which is particularly difficult to remove, either mechanically or chemically.

According to a solution typically adopted in order to solve this problem, the reaction chamber is dismounted periodically from the reactor and cleaned mechanically and/or chemically; this operation is lengthy and therefore implies that the reactor must remain out of service for a long time; besides, after a certain number of such cleaning operations, the chamber must be discarded or treated.

According to a recently proposed solution, reaction chamber cleaning processes are carried out (without dismounting the chamber) by heating the chamber at high temperature and letting appropriate gases flow therethrough; such cleaning processes can be carried out, for example, after a certain number of normal production processes (loading, heating, depositing, cooling, unloading).

The Applicant has noticed that the solutions known in the art adopt a “remedial” approach, i.e. the undesired material is removed after having deposited, and has thought that a “preventive” approach might be adopted instead, i.e. avoiding undesired material from depositing.

The general object of the present invention is to provide a solution for the above problems by adopting a “preventive” approach.

This object is substantially achieved through the reaction chamber for an epitaxial reactor having the features set out in independent claim 1 and through the process for heating a reaction chamber of an epitaxial reactor having the functionalities set out in independent claim 15; additional advantageous aspects of the chamber and method are set out in the dependent claims.

The present invention is based on the idea of differentiating the temperature of the reaction chamber walls, and thus of the reaction cavity.

Of course, the present invention does not necessarily exclude any cleaning operations to be carried out on a dismounted or non-dismounted chamber, but it considerably reduces the need and/or frequency thereof.

The present invention will become more apparent from the following description and from the annexed drawings, wherein:

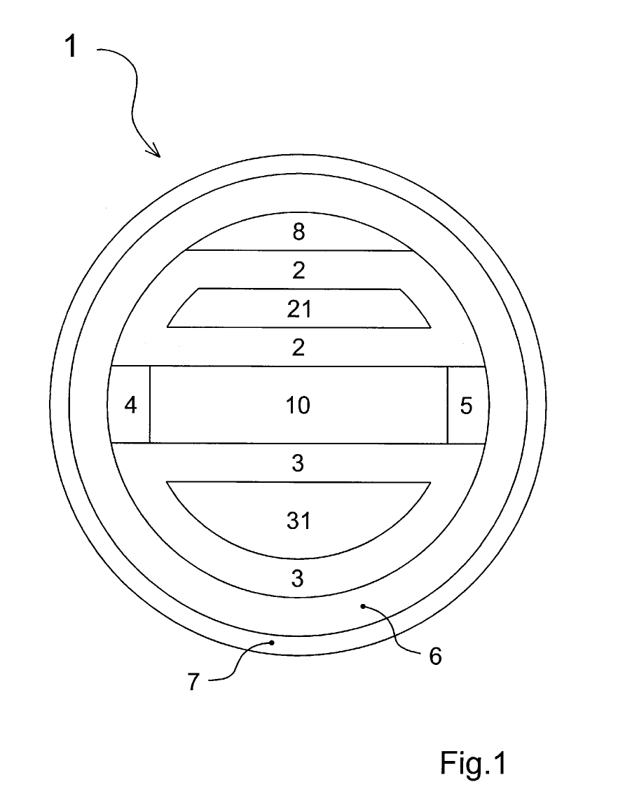

FIG. 1 is a schematic cross-sectional view of a first embodiment of the reaction chamber according to the present invention,

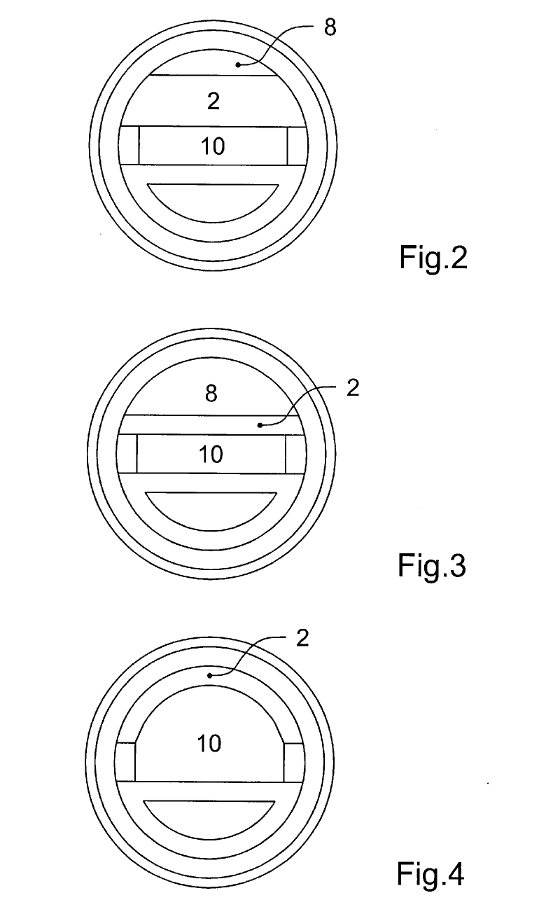

FIG. 2 is a schematic cross-sectional view of a second embodiment of the reaction chamber according to the present invention,

FIG. 3 is a schematic cross-sectional view of a third embodiment of the reaction chamber according to the present invention,

FIG. 4 is a schematic cross-sectional view of a fourth embodiment of the reaction chamber according to the present invention, and

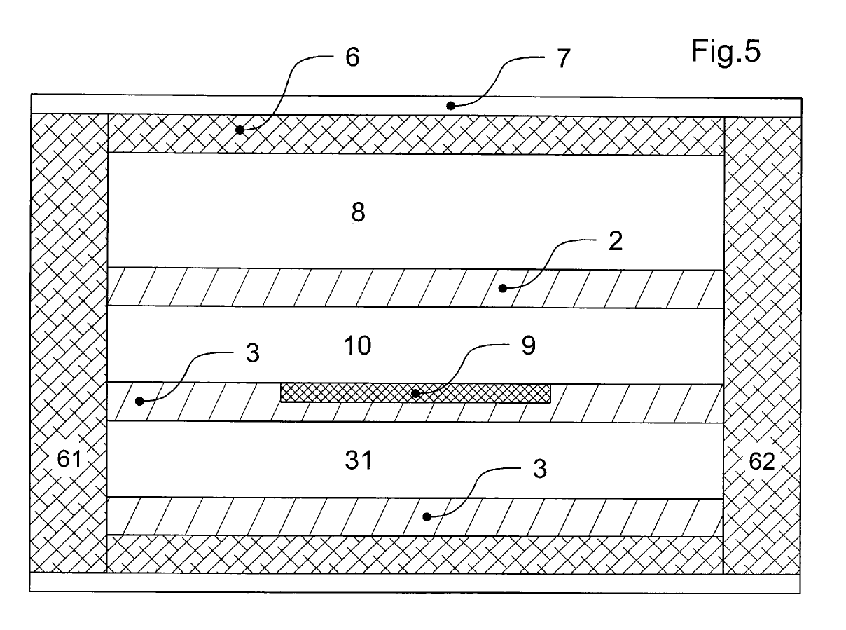

FIG. 5 is a schematic longitudinal view of the reaction chamber of FIG. 3.

Both this description and the aforementioned drawings are intended simply as explanatory and thus non-limiting examples; besides, it should be taken into consideration that said drawings are schematic and simplified.

In all figures, the reaction chambers are shown as arranged in their operating condition, i.e. when they have been inserted in an epitaxial reactor (not shown) and can treat substrates; in particular, the reactor is an epitaxial reactor for the deposition of layers of silicon carbide.

In the description of the various embodiments, the same reference numerals will be used to designate equivalent items.

FIG. 1 shows an example of an assembly consisting of a reaction chamber, designated as a whole by reference numeral 1, a shell, designated as a whole by reference numeral 6, which surrounds chamber 1, and a tube, designated by reference numeral 7, which surrounds shell 6.

Chamber 1 extends evenly in a horizontal direction and is made up of four walls; an upper wall 2, a lower wall 3 and two side walls, in particular a left-hand wall 4 and a right-hand wall 5. When these four walls 2,3,4,5 are joined together, they delimit an inner reaction cavity 10.

Tube 7 has a circular cross-section and is made of quartz (i.e. an inert and refractory material). Shell 6 has a body shaped essentially like a tube, has a circular cross-section, and is inserted in tube 7; shell 6 is made of fibrous or porous graphite (i.e. a thermally insulating and refractory material). The reaction chamber is substantially cylindrical in shape and is inserted in shell 6 so that its walls remain joined together. The outer shape of lower wall 3 has a half-moon cross-section; the outer shape of upper wall 2 has a cut half-moon cross-section; both walls are hollow, and their cavities are central and have a substantially constant thickness (thus cavity 31 of wall 3 has a half-moon shape and cavity 21 of wall 2 has a cut half-moon shape); cavity 21 of wall 2 is smaller than cavity 31 of wall 3. Since upper wall 2 is cut, a space 8 is defined between upper wall 2 and shell 6. Walls 4 and 5 are substantially equal and have a substantially rectangular cross-section (there is a slight convexity on one side, matching shell 6); side walls 4 and 5 rest on lower wall 3 and support upper wall 2; there may also be, for example, small projections and/or recesses (not shown) to ensure a precise and correct mutual positioning of the walls. Cavity 10 has a rectangular cross-section and is rather low and wide. Walls 2 and 3 of the reaction chamber are made of graphite (so provided as to be an electrically conducting, thermally conducting and refractory material); a protective coating layer (typically made of SiC or TaC) may be provided on these walls, particularly on the side facing cavity 10. Walls 4 and 5 of the reaction chamber may advantageously be made of silicon carbide (so provided as to be a refractory, thermally conducting and electrically insulating material); as an alternative to silicon carbide, boron nitride may be used instead; said walls may also be made of graphite coated with, for example, a thick layer of silicon carbide to keep walls 2 and 3 electrically insulated from each other.

An assembly similar to that of FIG. 1 has been described in detail in Patent Applications WO 2004/053187 and WO 2004/053188 in the name of the present Applicant, whereto reference should be made.

The reaction chamber of FIG. 2 differs from the one of FIG. 1 in that the outer shape of upper wall 2 has a cut half-moon cross-section, but it is not hollow.

The reaction chamber of FIG. 3 differs from the one of FIG. 1 in that upper wall 2 is shaped substantially like a flat plate; thus, a large space 8 is defined between upper wall 2 and shell 6.

The reaction chamber of FIG. 4 differs from the one of FIG. 1 in that upper wall 2 is shaped substantially like a convex plate and is substantially adjacent to shell 6; thus, cavity 10 no longer has a rectangular cross-section (as in the example of FIG. 1), but a flat cross-section at the bottom and a circular cross-section at the top.

In the examples of FIG. 1, FIG. 2 and FIG. 3, space 8 remains empty; alternatively, it may be filled wholly or partially with a thermally insulating material (e.g. fibrous or porous graphite), but an equivalent effect may also be obtained by shaping shell 6 appropriately.

In the examples of FIG. 1, FIG. 2 and FIG. 3, the reaction chamber (consisting of the assembly of walls 2, 3, 4 and 5 joined together in such a way as to delimit inner reaction chamber 10) has a substantially but not perfectly cylindrical shape because wall 2 is flat on top; in fact, it is a cylinder cut on one side parallel to the cylinder axis, in particular cut according to a plane being parallel to the cylinder axis. In the example of FIG. 4, the reaction chamber is perfectly cylindrical in shape.

For all of the above-described assemblies shown in the drawings, there is typically one or more inductors wound around tube 7 and adapted to heat the reaction chamber 1 and the walls thereof, in particular upper wall 2 and lower wall 3, by induction.

As far as shell 6 is concerned (as shown in all illustrated examples), in addition to having a tube-like body, it also has two lids, in particular a front lid 61 and a rear lid 62, in particular both having a circular shape. Said lids are shown in FIG. 5, which is a longitudinal-section view of the assembly of FIG. 3; it should be noted that lids 61 and 62 as shown in FIG. 5 are simplified and do not have any apertures, which are nonetheless generally present at least for the inlet of reaction gases into reaction cavity 10 (from the left) and for the outlet of exhausted gases from reaction cavity 10 (from the right).

FIG. 5 shows a (rotatable) substrate support 9 inserted in a recess of lower wall 3, so that its top surface is substantially aligned with the top surface of wall 3; support 9 has a disc-like shape and has pockets (not shown) adapted to accommodate substrates; support 9 is made of graphite (typically coated with a SiC or TaC layer), and thus it is also used as a substrate susceptor.

For the sake of completeness, some dimensional indications are given below relating to the reaction chambers of FIG. 3 and FIG. 5, which substantially also apply to the reaction chambers of FIG. 1, FIG. 2 and FIG. 4.

Reaction chamber 1 extends evenly along a longitudinal axis for a length of 300 mm, and the outer shape of its cross-section is a segment of a circle (i.e. a cut circle) having a diameter of 270 mm; alternatively, said cross-section may have a (possibly cut) polygonal shape or a (possibly cut) elliptical shape. The inner shape of the cross-section of cavity 10 is substantially a rectangle being 210 mm wide and 25 mm high. Support 9 is shaped like a thin disc having a diameter of 190 mm and a thickness of 5 mm. Side walls 4 and 5 have a thickness of 5 (or 10 or 15) mm; upper wall 2 is 15 mm thick; lower wall 3 is 15 mm thick (in particular, this thickness refers to that area of the hollow half-moon which is adjacent to cavity 10).

Of course, the above-mentioned dimensions are merely exemplificative. However, they are useful to give an idea of the dimensions of the reaction chambers taken into account by the present invention; as a matter of fact, each dimension may be approximately 50% smaller and approximately 100% greater, remembering that direct scalability is not applicable anyway.

As said, the present invention is based on the idea of differentiating the temperature of the reaction chamber walls, and thus of the reaction cavity.

In general, the method according to the present invention relates to a (hot-wall) reaction chamber of an epitaxial reactor provided with walls delimiting said reaction chamber, wherein at least or only one first chamber wall is heated less that a second chamber wall. In the illustrated examples, the colder wall is upper wall 2, whereas the hotter wall if lower wall 3; the effect of side walls 4 and 5 is not particularly significant.

In particular, according to the present invention, at least or only one first chamber wall is heated less that any other chamber wall.

In accordance with the aforementioned principles, there will be a lesser growth of material on said colder wall, and therefore said wall will be less subject to particle detachment; of course, the colder wall shall be chosen appropriately.

In many epitaxial reactors, substrates are supported (either directly or indirectly) by a substantially horizontal lower wall of the reaction chamber, and are located directly underneath an upper wall of the reaction chamber. Therefore, any particles coming off the upper wall will likely fall onto one of the underlying substrates, thus causing damage to the growing layer; this is true even when the gas flow within the chamber is substantially parallel to both the upper and lower walls (as in the illustrated examples). In this case, it is advantageous that the hotter wall is the lower one, so that substrates get very hot, and that the colder wall is the upper one, so that growth due to material deposition is limited.

It is worth pointing out, for example by referring to FIG. 5, that the lower surface portions (3) upstream and downstream of susceptor 9 have a lower temperature than susceptor 9, since they are located close to the gas inlet and to the gas outlet, respectively (which causes a reduced growth); furthermore, any particles coming off the downstream portion of susceptor 9 (i.e. on the right) end up directly into the gas outlet and therefore cannot cause any damage; finally, any particles coming off the upstream portion of susceptor 9 (i.e. on the left) tends to be carried by the reaction gas flow and do not fall onto the substrates housed in or on susceptor 9.

In epitaxial reactors for silicon carbide, i.e. operating at high temperature, the best heating method is induction heating; all illustrated examples are conceived for such a heating method.

A first possibility according to the present invention consists in providing single heating means for the chamber walls and in providing walls having at least a first and a second configurations; the first and second configurations differ from each other in that the first configuration is heated less than the second configuration. This is the solution adopted in the illustrated examples; in fact, in the example of FIG. 1, the configuration difference relates to both the size (and shape) of the walls (2,3) and the size of the cavities (21,31) of the walls (2,3); in the example of FIG. 2, the configuration difference relates to both the size (and shape) of the walls (2,3) and the presence/absence of a cavity; in the examples of FIG. 3 and FIG. 4, the configuration difference relates to the shape of the wall section.

A second possibility according to the present invention consists in providing first heating means and second heating means, wherein the first heating means are used for heating at least or solely the first wall and the second heating means are used for heating the second wall or all other chamber walls.

However, said second possibility does not exclude the use of walls having at least a first and a second configurations, the first and second configurations differing from each other, in particular so that the first configuration is heated less than the second configuration.

The solution of FIG. 1 or a similar solution, i.e. including two walls with through holes, can also be advantageously used for obtaining differentiated heating through another physical phenomenon; a cooling gas, preferably hydrogen or helium, can be made to flow through both through holes, thus controlling the temperature of both walls by controlling one or two gas flows. Of course, this solution can also be applied to a higher number of walls with through holes.

In general, in addition or as an alternative to using different configurations, differentiated heating can also be obtained by using different materials for the chamber walls.

In the light of the above explanations, it is important to choose the most appropriate temperatures for the reaction chamber walls.

It is now worth specifying that during an epitaxial growth process, in general, temperature is initially increased up to a maximum value, after which said maximum value is maintained for the deposition time and is then decreased, for example, to 100° C.-200° C.

According to the present invention, the first wall is heated up till a first maximum temperature and the second wall is heated up till a second maximum temperature, i.e. the maximum temperatures of the two walls are different.

As concerns the first wall (typically the lower wall, on which substrates are laid directly or indirectly), the maximum temperature is comprised between 1,500° C. and 1,650° C., which are ideal temperatures for growing thin layers of silicon carbide.

As concerns the second wall (typically the wall above the substrates), the maximum temperature is preferably lower than that of the first wall by 150° C. to 300° C.

Of course, tests shall be carried out in order to identify optimal conditions depending on the shape and size of the chamber and according to the process used.

In general, the reaction chamber according to the present invention is used for epitaxial reactors and is provided with walls which (when joined together) delimit an inner cavity, specifically a lower wall and an upper wall and at least two side walls; the lower wall and the upper wall have different configurations and/or are made of different materials; this allows the two walls to be heated differently, thus reaching different temperatures.

The lower wall and/or the upper wall are substantially horizontal when the chamber is in operating conditions.

Preferably, the side walls are substantially vertical when the chamber is in operating conditions.

Externally, the chamber walls should be surrounded wholly or partially by thermally insulating material, in particular in the form of one or more elements; typical materials used for these applications are porous graphite and fibrous graphite.

A very advantageous shape of the reaction chamber according to the present invention is the substantially cylindrical one, with the cylinder axis being substantially horizontal when the chamber is in operating conditions; this is the case of all examples shown in the drawings. However, elliptic cross-section cylinders or prisms (possibly cut) may be taken into consideration as well.

In this case, the inner cavity may advantageously be located along the cylinder axis and have a cross-section being substantially rectangular (preferably low and wide) and substantially even along the cylinder axis; this is the case of the examples of FIG. 1, FIG. 2 and FIG. 3.

A particularly advantageous shape of the lower wall is the one substantially resembling a hollow half-moon, as is the case of all examples shown in the drawings; several remarks about this shape are included in Patent Applications WO 2004/053187 and WO 2004/053188, whereto reference should be made.

As far as the upper wall is concerned, good results may be attained with shapes substantially resembling a flat or convex plate and a whole or cut, solid or hollow half-moon.

The solution employing hollow differentiated-heating/temperature walls (as in the particular example of FIG. 1) deserves special attention; in this case, it is possible to provide the walls in such a way that the lower wall has a first cavity and the upper wall has a second cavity; the first cavity and the second cavity may have different dimensions, in particular different cross-sections.

As said, the purpose of the configuration and material choices relating to the walls is to cause a different heating, typically by induction, of the walls themselves; in particular, the aim is to heat the lower wall to a higher temperature than the upper wall, typically by induction.

An advantageous solution for epitaxial reactors, in particular for hot-wall epitaxial reactors, for growing silicon carbide layers, is to use graphite for manufacturing the chamber walls and to provide the chamber walls, in particular the lower wall and/or the upper wall, with a coating layer (at least on the side facing the reaction cavity) made of SiC [silicon carbide] or TaC [tantalum carbide] or NbC [niobium carbide] or alloys thereof.

Both the heating method according to the present invention as defined above and the reaction chamber according to the present invention as defined above are specifically adapted to be used, alone or in combinations thereof, in an epitaxial reactor, in particular an epitaxial reactor of the induction-heated type.

When induction heating is used, one or several inductors transfer energy to the chamber walls through electromagnetic waves; such electromagnetic waves in the chamber walls (in particular in those made of electrically conducting material) generate electric currents by electromagnetic induction; in the chamber walls, these electric currents generate heat by Joule effect; this heat is partly dissipated to the outside environment (through shell 6 and tube 7 in the examples of the drawings) and is partly transferred to the inner reaction cavity of the chamber (cavity 10 in the examples of the drawings). In stationary conditions, the temperature of the chamber remains constant and the energy transferred by one or several inductors is entirely dissipated as heat to the environment outside the reaction chamber.

The energy transfer from an inductor to a reaction chamber wall depends on various factors, among which: intensity and frequency of the current flowing through the inductor, electric resistivity and magnetic permeability of the wall, shape and size of the inductor, shape and size of the wall, length of the outer sectional perimeter of the wall.

In the light of these considerations, the temperature of the reaction chamber walls can be differentiated in three ways for the purposes of the present invention as follows:
A) the length of the outer sectional perimeter of the upper wall is shorter than the length of the outer sectional perimeter of the lower wall, or
B) the area of the outer sectional perimeter of the upper wall is smaller than the area of the outer sectional perimeter of the lower wall, or
C) both A and B.

When designing a reaction chamber according to the present invention, it is necessary to take into account the fact that the currents induced in a wall tend to flow towards the outer sectional perimeter of the wall; for graphite, most of the current localizes within a perimetric layer of 8-10 mm (a design value of 15 mm ensures that all current is taken into account); it follows that using thin walls (e.g. thinner than 10 mm) would be detrimental for the energy transfer between the inductor and the wall.

The advantages of the heating method and of the reaction chamber are particularly important for reactors used for silicon carbide epitaxial growth processes.

1. Reaction chamber for an epitaxial reactor, provided with walls delimiting an inner cavity, specifically a lower wall and an upper wall and at least two side walls, and with means for heating the chamber walls, wherein said lower wall and said upper wall have different configurations and/or are made of different materials, and wherein said different configurations and/or said different materials are such as to cause said lower wall to be heated to a higher temperature than said upper wall.

2. Reaction chamber according to claim 1, wherein said lower wall and/or said upper wall are substantially horizontal when the chamber is in operating conditions.

3. (canceled)

4. (canceled)

5. Reaction chamber according to claim 1, wherein the chamber is substantially shaped like a cylinder, the axis of said cylinder being substantially horizontal when the chamber is in operating conditions and wherein said cavity is arranged along the axis of said cylinder and has a cross-section being substantially rectangular and substantially even along the cylinder axis.

6. (canceled)

7. Reaction chamber according to claim 1, wherein the lower wall is shaped substantially like a hollow half-moon and wherein the upper wall is shaped substantially like a half-moon or a plate.

8. (canceled)

9. (canceled)

10. Reaction chamber according to claim 1, wherein the lower wall has a first cavity and the upper wall has a second cavity, said first cavity and said second cavity having in particular different dimensions.

11. Reaction chamber according to claim 1, wherein the length and/or area of the outer sectional perimeter of said upper wall is accordingly smaller than the length and/or area of the outer sectional perimeter of said lower wall.

12. Reaction chamber according to claim 1, wherein said different configurations and/or said different materials are such as to cause said lower wall and said upper wall to be heated by induction differently.

13. (canceled)

14. (canceled)

15. Method for heating a reaction chamber of an epitaxial reactor, the reaction chamber being provided with walls delimiting it, wherein said chamber has a substantially horizontal lower wall and a substantially horizontal upper wall, said lower wall being adapted to support substrates and wafers either directly or indirectly, the method comprising heating at least or only one first wall of said chamber less than a second wall of said chamber, wherein said first wall is said upper wall and said second wall is said lower wall.

16. (canceled)

17. (canceled)

18. (canceled)

19. Method according to claim 15, wherein there are provided single induction heating means for the chamber walls and walls having at least a first and a second configurations, said first and said second configurations differing from each other in that the first configuration is heated less than the second configuration.

20. (canceled)

21. Method according to claim 15, wherein there are provided first induction heating means and second induction heating means, and wherein the first heating means are used for heating at least or only said first wall and the second heating means are used for heating said second wall or all the other walls of the chamber.

22. (canceled)

23. (canceled)

24. Method according to claim 15, wherein the chamber walls are made of different materials.

25. Method according to claim 15, wherein said first wall is heated up till a first maximum temperature and said second wall is heated up till a second maximum temperature, and wherein the difference between said second maximum temperature and said first maximum temperature is comprised between 150° C. and 300° C.

26. Method according to claim 25, wherein said second maximum temperature is comprised between 1,500° C. and 1,650° C.

27. (canceled)

28. Method according to claim 25, wherein the chamber is heated up till said first and second maximum temperatures during epitaxial growth processes in said chamber, in particular during processes for the epitaxial growth of silicon carbide.

29. (canceled)

30. (canceled)

31. Epitaxial reactor comprising at least one reaction chamber, wherein said reaction chamber is according to any of claims 1 to 7 and/or wherein the reactor is adapted to implement the heating method according to any of claims 15 to 28 in order to heat said chamber.

32-33. (canceled)
